(19) United States
(12) Patent Application Publication
(10) Pub. No.: US 2020/0122450 A1
(43) Pub. Date: Apr. 23, 2020

(54) TOLERANCE COMPENSATION ELEMENT FOR CIRCUIT CONFIGURATIONS

(71) Applicant: Siemens Aktiengesellschaft, Muenchen (DE)

(72) Inventors: Rene BLANK, Berlin (DE); Martin FRANKE, Berlin (DE); Peter FRUEHAUF, Falkensee (DE); Ruediger KNOFE, Teltow (DE); Bernd MUELLER, Falkenberg (DE); Stefan NERRETER, Heidesee OT Blossin (DE); Joerg STROGIES, Berlin (DE); Klaus WILKE, Berlin (DE)

(73) Assignee: Siemens Aktiengesellschaft, Muenchen (DE)

(21) Appl. No.: 16/627,529

(22) PCT Filed: Jun. 7, 2018
(86) PCT No.: PCT/EP2018/064983

§ 371 Date: Dec. 30, 2019

(30) Foreign Application Priority Data
Jul. 4, 2017 (DE) 10 2017 211 330.8

(51) Int. Cl. B33Y 80/00; H05K 3/46; H05K 1/18

(52) U.S. Cl. CPC B33Y 80/00; H01L 24/83; H05K 1/186; H05K 3/4614

(57) ABSTRACT

A tolerance compensation element is for circuit configurations having a DCB (direct copper bonded) substrate and a PCB (printed circuit board). A circuit configuration further includes the tolerance compensation element. A tolerance compensation element is positioned in a targeted manner between the DCB substrate and PCB in a gap A for the contact-connection of components on the DCB substrate via additive manufacturing and is formed so as to close the gap.

### PRIORITY STATEMENT

This application is the national phase under 35 U.S.C. § 371 of PCT International Application No. PCT/EP2018/064983 which has an International filing date of Jun. 7, 2018, which designated the United States of America and which claims priority to German patent application no. DE 102017211330.8 filed Jul. 4, 2017, the entire contents of each of which are hereby incorporated herein by reference.

### FIELD

Embodiments of the invention generally relate to a tolerance compensation element for circuit configurations with a DCB (Direct Copper Bonded) substrate and a PCB (Printed Circuit Board) circuit board and to a circuit configuration with this tolerance compensation element.

### BACKGROUND

For the contacting of both sides of semiconductor components (bare dies) in power electronics in PCB (circuit board) cavities, the depth of this cavity must be adapted quite accurately to the overall height of the semiconductor components. Due to the production tolerances in PCB manufacture, in particular during the milling of the cavity, and with the selected material properties of the glass fiber/resin composite materials used, the required narrow tolerances are not always reliably achieved.

In addition, there is the necessity to process different semiconductor components, which may originate from different sources. In this case, the overall heights cannot always be influenced, and so that gives rise to the technical problem of having to compensate for overall heights that differ considerably, i.e. differences of >100 μm, in order to ensure reliable contacting. The resultant significant gap dimensions cannot be reliably closed by the compensating capacity of sintered or conventional soft-soldered connections. With a gap of small dimensions, a correspondingly dimensioned application of solder would lead to solder oozing out at the sides, whereby the high-voltage insulating properties would be significantly worsened. Correspondingly, with a gap of considerably greater dimensions, there would be a lack of solder, and so the thermal and possibly also electrical conductivities would be impaired.

At the same time, the overall height of each cavity must be adapted to the three-dimensional chip structure. In this respect, PCB procurement is problematic, since the variety of variants increases. It has not been possible so far to achieve a lowering of costs by scaling. In addition to this, there is the fact that the percentage of technically satisfactory final products in production is brought down by the tolerances of the process that are caused by the milling of the cavity.

Another solution is a 100% individual measurement of the other part to be joined, with a subsequent individually dimensioned application of solder. This method combines two additional processes, measurement and individual application of solder, with all the negative consequences that entails for the costs and throughput times.

### SUMMARY

At least one embodiment of the present invention is directed to a tolerance compensation element for circuit configurations, in particular electronic circuit configurations, and also a circuit configuration that can be produced individually in an easy way.

At least one embodiment of the invention is directed to a tolerance compensation element, in particular for electronic circuit configurations. Advantageous forms and developments that can be used individually or in combination with one another are the subject of the claims.

According to at least one embodiment of the invention, a tolerance compensation element is usable for circuit configurations, in particular electronic circuit configurations, with a DCB (Direct Copper Bonded) substrate and a PCB (Printed Circuit Board) circuit board. At least one embodiment of the invention may be distinguished by the fact that a tolerance compensation element is specifically set between the DCB substrate and the PCB circuit board in a gap A for the contacting of components on the DCB substrate by means of additive manufacturing and is formed in a gap-closing manner.

At least one embodiment of the invention is further directed to a circuit configuration according to at least one embodiment of the invention with a tolerance compensation element having the properties described above or below.

### BRIEF DESCRIPTION OF THE DRAWINGS

Further embodiments and advantages of the invention are explained below on the basis of an example embodiment and on the basis of the drawing,

in which:

FIG. 1 shows a circuit arrangement with a tolerance compensation element according to an embodiment of the invention in a schematic representation.

### DETAILED DESCRIPTION OF THE EXAMPLE EMBODIMENTS

According to at least one embodiment of the invention, a tolerance compensation element is usable for circuit configurations, in particular electronic circuit configurations, with a DCB (Direct Copper Bonded) substrate and a PCB (Printed Circuit Board) circuit board. At least one embodiment of the invention may be distinguished by the fact that a tolerance compensation element is specifically set between the DCB substrate and the PCB circuit board in a gap A for the contacting of components on the DCB substrate by means of additive manufacturing and is formed in a gap-closing manner.

In at least one embodiment, in order to ensure the gap dimensions for reliable contacting of the electrical component, in particular the semiconductor component, both on the upper side and on the underside, in a closely toleranced range, a gap A between the PCB circuit board and the DCB substrate is initially produced with an undersize in the manufacturing process of the PCB circuit board, and so there is a defined distance between the DCB substrate (Direct Copper Bond) and the PCB (Printed Circuit Board) circuit board.

At least one embodiment of the invention includes that this distance is set in a defined manner in the gap A and closed by means of a tolerance compensation element, in particular an AM layer, by means of an additive manufacturing process. In this case, it is provided that the tolerance compensation element, that is to say the AM layer, is applied either to the PCB circuit board or the DCB substrate, preferably in the form of a powder, and is melted in a punctiform manner, in particular by means of a laser beam. It is of advantage if the tolerance compensation element is manufactured from a material or an alloy that can be wetted for conventional solder materials, in order that this tolerance compensation element can be attached in a material-bonding manner in the subsequent soldering process. The distance between the DCB substrate and the PCB circuit board may be determined directly in the implemented production process and be set workpiece-specifically for the respective pairing of DCB substrate and PCB circuit board by means of a closed control loop.

A continuation of the concept according to at least one embodiment of the invention may reside in that the DCB substrate comprises a copper-aluminum-copper arrangement (dielectric).

A specific refinement of this concept according to at least one embodiment of the invention may reside in that the DCB substrate comprises a copper-ceramic-copper arrangement.

An advantageous refinement of the concept according to at least one embodiment of the invention may reside in that the tolerance compensation element is applied in gap A either to the PCB circuit board or the DCB substrate and melted in a punctiform manner.

A continuation of the concept according to at least one embodiment of the invention may reside in that the tolerance compensation element can be melted in the gap A by means of a laser beam.

A specific refinement of this concept according to at least one embodiment of the invention may reside in that a component to be electrically contacted is a semiconductor component.

An advantageous refinement of the concept according to at least one embodiment of the invention may reside in that the gap A between the PCB circuit board and the DCB substrate is produced with an undersize in the production process of the PCB circuit board, and so a specific distance is formed between the DCB substrate and the PCB circuit board.

A continuation of the concept according to at least one embodiment of the invention may reside in that the gap dimensions for the electrical contacting of the semiconductor component are formed in a closely toleranced range both for a gap B on the upper side and in a gap C on the underside of the semiconductor component.

A specific refinement of this concept according to at least one embodiment of the invention may reside in that the tolerance compensation element is formed from a material or an alloy that can be wetted for solder materials.

An advantageous refinement of the concept according to at least one embodiment of the invention may reside in that the distance in the gap A can be determined directly in the production process and is set material-specifically for the respective pairing of DCB substrate and PCB circuit board by means of a closed control loop.

At least one embodiment of the invention is further directed to a circuit configuration according to at least one embodiment of the invention with a tolerance compensation element having the properties described above or below.

The tolerance compensation element according to at least one embodiment of the invention is arranged between a DCB (Direct Copper Bonded) substrate and a PCB (Printed Circuit Board) circuit board. The PCB circuit board forms over the DCB substrate a cavity in which a component, in particular a semiconductor component, can be positioned. For the case where the electronic component is a semiconductor component, the DCB substrate is formed in a three-layered manner in the composition copper-ceramic-copper. Other components that accept a dielectric as the DCB substrate with a composition copper-aluminum-copper are also conceivable.

The semiconductor component has an upper side, which forms a gap B in relation to the PCB circuit board. Moreover, the semiconductor component has an underside, which is positioned over a gap C in relation to the DCB substrate.

In order to ensure the gap dimensions for reliable contacting of the electrical component, in particular the semiconductor component, both on the upper side (gap B) and on the underside (gap C), in a closely toleranced range, the gap A between the PCB circuit board and the DCB substrate is initially produced with an undersize in the manufacturing process of the PCB circuit board, and so there is a defined distance between the DCB substrate (Direct Copper Bond) and the PCB (Printed Circuit Board) circuit board. It is provided that this distance is set in a defined manner in the gap A and closed by means of a tolerance compensation element, in particular an AM layer, by means of an additive manufacturing process. In this case, it is also provided that the tolerance compensation element, that is to say the AM layer, is applied either to the PCB circuit board or the DCB substrate, preferably in the form of a powder, and is melted in a punctiform manner, in particular by means of a laser beam.

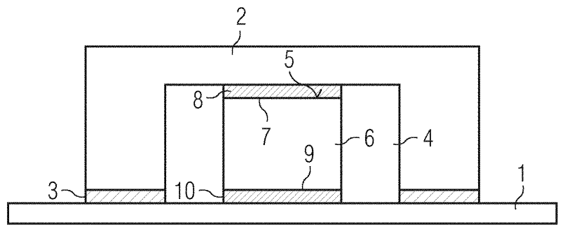

FIG. 1 shows a circuit arrangement with a tolerance compensation element according to an embodiment of the invention, which is arranged between a DCB (Direct Copper Bonded) substrate 1 and a PCB (Printed Circuit Board) circuit board 2 in a gap A 3. The PCB circuit board 2 forms over the DCB substrate 1 a cavity 4, in which an electronic component 5, in particular a semiconductor component 6, can be positioned. In the case where the electronic component 5 is a semiconductor component 6, the DCB substrate 1 is formed in a three-layered manner, preferably in the composition copper-ceramic-copper. Other components 5 that accept a dielectric as the DCB substrate 1 with a composition copper-aluminum-copper are also conceivable.

The semiconductor component 6 has an upper side 7, which forms a gap B 8 in relation to the PCB circuit board 2. The semiconductor component 6 also has an underside 9, which is positioned over a gap C 10 in relation to the DCB substrate 1.

In order to ensure the gap dimensions for reliable contacting of the electrical component 5, in particular the semiconductor component 6, both on the upper side (gap B, 8) and on the underside (gap C, 10), in a closely toleranced range, the gap A 3 between the PCB circuit board 2 and the DCB substrate 1 is initially produced with an undersize in the manufacturing process of the PCB circuit board 2, and so there is a defined distance between the DCB substrate (Direct Copper Bond) 1 and the PCB (Printed Circuit Board) circuit board 2. It is provided that this distance is set in a defined manner in the gap A 3 and closed by means of a tolerance compensation element, in particular an AM layer, by means of an additive manufacturing process. In this case, it is also provided that the tolerance compensation element, that is to say the AM layer, is applied either to the PCB circuit board 2 or the DCB substrate 1, preferably in the form of a powder, and is melted in a punctiform manner, in particular by means of a laser beam.

The tolerance compensation element according to an embodiment of the invention for electronic circuit configurations is distinguished by the fact that it can be designed and manufactured in an easy, individual way in an additive manufacturing process for closing the gap between a DCB substrate and a PCB circuit board.

Although the invention has been illustrated and described in greater detail by the example embodiment, the invention is not limited by the disclosed examples, and other variations can be derived therefrom by a person skilled in the art without departing from the scope of protection of the invention.

### LIST OF DESIGNATIONS

1 DCB (Direct Copper Bonded) substrate
2 PCB (Printed Circuit Board) circuit board
3 Gap A
4 Cavity
5 Electronic component
6 Semiconductor component
7 Upper side
8 Gap B
9 Underside
10 Gap C

1. A tolerance compensation element for circuit configurations with a DCB (Direct Copper Bonded) substrate and a PCB (Printed Circuit Board), the tolerance compensation element being set between the DCB substrate and the PCB in a gap for contacting of components on the DCB substrate via additive manufacturing, and being formed in a gap-closing manner.

2. The tolerance compensation element of claim 1, wherein the DCB substrate includes a copper-aluminum-copper arrangement.

3. The tolerance compensation element of claim 1, wherein the DCB substrate includes a copper-ceramic-copper arrangement.

4. The tolerance compensation element of claim 1, wherein the tolerance compensation element is applied in the gap, either to the PCB or the DCB substrate, and melted in a punctiform manner.

5. The tolerance compensation element of claim 4, wherein the tolerance compensation element is meltable in the gap via a laser beam.

6. The tolerance compensation element of claim 3, wherein a component to be electrically contacted is a semiconductor component.

7. The tolerance compensation element of claim 6 the gap between the PCB and the DCB substrate is produced with an undersize in a manufacturing process of the PCB, and such that a specified distance is formed between the DCB substrate and the PCB.

8. The tolerance compensation element claim 6, wherein dimensions of the gap for the electrical contacting of the semiconductor component are formed in a closely toleranced range both for another gap B, on an upper side of the semiconductor component and a further gap, on an underside of the semiconductor component.

9. The tolerance compensation element of claim 6, wherein the tolerance compensation element is formed from a material or an alloy, wettable for solder materials.

10. The tolerance compensation element of claim 1, wherein a distance in the gap is determinable directly in a production process and is set workpiece-specifically for a respective pairing of DCB substrate and PCB via of a closed control loop.

11. A circuit configuration comprising the tolerance compensation element of claim 1.

12. The tolerance compensation element of claim 2, wherein the tolerance compensation element is applied in the gap, either to the PCB or the DCB substrate, and melted in a punctiform manner.

13. The tolerance compensation element of claim 12, wherein the tolerance compensation element is meltable in the gap via a laser beam.

14. The tolerance compensation element of claim 3, wherein the tolerance compensation element is applied in the gap, either to the PCB or the DCB substrate, and melted in a punctiform manner.

15. The tolerance compensation element of claim 14, wherein the tolerance compensation element is meltable in the gap via a laser beam.

16. The tolerance compensation element of claim 4, wherein a component to be electrically contacted is a semiconductor component.

17. The tolerance compensation element of claim 16 the gap between the PCB and the DCB substrate is produced with an undersize in a manufacturing process of the PCB, and such that a specified distance is formed between the DCB substrate and the PCB.

18. The tolerance compensation element of claim 5, wherein a component to be electrically contacted is a semiconductor component.

19. The tolerance compensation element of claim 18, the gap between the PCB and the DCB substrate is produced with an undersize in a manufacturing process of the PCB, and such that a specified distance is formed between the DCB substrate and the PCB.

20. The tolerance compensation element of claim 2, wherein a distance in the gap is determinable directly in a production process and is set workpiece-specifically for a respective pairing of DCB substrate and PCB via of a closed control loop.
